(19) United States
(12) Patent Application Publication
(10) Pub. No.: US 2024/0146244 A1
(43) Pub. Date: May 2, 2024

(54) SEMICONDUCTOR INTEGRATED CIRCUIT

(71) Applicant: ROHM CO., LTD., Kyoto (JP)

(72) Inventors: Shun Fukushima, Kyoto (JP); Daichi NAKAJIMA, Kyoto (JP)

(21) Appl. No.: 18/384,554

(22) Filed: Oct. 27, 2023

(30) Foreign Application Priority Data
Oct. 28, 2022 (JP) 2022-173690

(51) Int. Cl. H03B 5/24

(52) U.S. Cl. CPC H03B 5/24; H03K 19/20

(57) ABSTRACT

A semiconductor integrated circuit includes: a first oscillator configured to generate a first clock signal having a first frequency; and at least one second oscillator configured to generate a second clock signal having a second frequency lower than the first frequency, wherein the first oscillator has relatively higher frequency accuracy than the at least one second oscillator, and wherein the at least one second oscillator is capable of being calibrated by using the first clock signal, and the first oscillator is capable of being stopped during a non-calibration period.

### CROSS-REFERENCE TO RELATED APPLICATION

This application is based upon and claims the benefit of priority from Japanese Patent Application No. 2022-173690, filed on Oct. 28, 2022, the entire contents of which are incorporated herein by reference.

### TECHNICAL FIELD

The present disclosure relates to a semiconductor integrated circuit including an oscillator.

### BACKGROUND

Clock signals are used in semiconductor integrated circuits for various purposes. A relaxation type oscillator is widely used as an oscillator that generate clock signals. The relaxation type oscillator includes a capacitor, a current source that charges the capacitor, a switch that discharges the capacitor, and a comparator that compares a voltage of the capacitor with a threshold value. When the capacitor is charged with a constant current, the voltage of the capacitor increases with a constant slope. If the comparator detects that the voltage of the capacitor has reached the threshold value, the switch is turned on to discharge the capacitor and resume charging the capacitor.

### BRIEF DESCRIPTION OF DRAWINGS

The accompanying drawings, which are incorporated in and constitute a part of the specification, illustrate embodiments of the present disclosure.

FIG. 1 is a circuit diagram of a semiconductor integrated circuit according to an embodiment.

FIG. 2 is a circuit diagram of a second oscillator.

FIG. 3 is a circuit diagram of a second oscillator according to Example 1.

FIG. 4 is a diagram illustrating an operation of the second oscillator shown in FIG. 3.

FIG. 5 is a circuit diagram of a second oscillator according to Example 2.

FIG. 6 is a diagram illustrating an operation of the second oscillator shown in FIG. 5.

FIG. 7 is a block diagram of a semiconductor integrated circuit.

FIG. 8 is a circuit diagram of a semiconductor integrated circuit.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### SUMMARY OF EMBODIMENT

A summary of some exemplary embodiments of the present disclosure will be described. As a prelude to the detailed description presented later, for the purpose of a basic understanding of the embodiments, this summary presents, in a simplified form, some concepts of one or more embodiments, but does not limit the scope of the present disclosure. Moreover, this summary is not a comprehensive overview of all possible embodiments and is not intended to limit essential elements of an embodiment. For the sake of convenience, “one embodiment” may be used to refer to one embodiment (example or variation) or multiple embodiments (examples or variations) disclosed herein.

A semiconductor integrated circuit according to one embodiment includes a first oscillator configured to generate a first clock signal having a first frequency, and at least one second oscillator configured to generate a second clock signal having a second frequency lower than the first frequency. The first oscillator has relatively higher frequency accuracy than the at least one second oscillator. The at least one second oscillator is capable of being calibrated by using the first clock signal, and the first oscillator is capable of being stopped during a non-calibration period.

By calibrating the at least one second oscillator using the first clock signal generated by the first oscillator having high frequency accuracy, it is possible to enhance the accuracy of the oscillation frequency of the at least one second oscillator. The first oscillator having high frequency accuracy consumes more power than the at least one second oscillator. However, by allowing the first oscillator to be stopped except during the calibration period of the at least one second oscillator, it is possible to suppress an increase in power consumption.

In one embodiment, the at least one second oscillator may be calibrated such that the second frequency is 1/K times the first frequency, where K is an integer equal to or greater than 8. This enables highly accurate calibration. K may be 16 or more, more preferably 32 or more. The larger K is, the higher the accuracy of the second frequency becomes.

In one embodiment, the at least one second oscillator may include a capacitor, a current source configured to charge the capacitor, a comparator configured to compare a ramp signal generated in the capacitor with a threshold voltage, and a calibration circuit configured to adjust the threshold voltage.

In one embodiment, the calibration circuit includes a first counter configured to count up in response to an up signal and count down in response to a down signal, a D/A converter configured to convert a count value of the first counter to the threshold voltage, and a controller configured to output the first clock signal as the up signal during a time difference between a period of the first clock signal and a period of the second clock signal if the period of the second clock signal is longer than a time of a predetermined number K times the period of the first clock signal, and output the second clock signal as the down signal if the period of the second clock signal is shorter than a time of a predetermined number K times the period of the first clock signal.

In one embodiment, the controller may include a second counter configured to count the first clock signal, assert a first control signal if a count value reaches a predetermined number K, and be reset by the second clock signal, and a logic circuit configured to output the first clock signal as the up signal while the first control signal is asserted and output the second clock signal as the down signal while the first control signal is negated.

In one embodiment, the logic circuit may include a first AND gate configured to output a logical product of the first clock signal and the first control signal as the up signal.

The logic circuit may include a second AND gate configured to output a logical product of the second clock signal and an inverted signal of the first control signal as the down signal.

In one embodiment, the calibration circuit may include a third counter configured to perform a counting operation in response to a trigger signal and have a count value reset in response to a reset signal, a D/A converter configured to convert the count value of the third counter to a threshold voltage, and a controller configured to output the first clock signal as the trigger signal until a next edge of the second clock signal is generated after K periods of the first clock signal have elapsed from an edge of the second clock signal.

In one embodiment, the controller may include a fourth counter configured to count the first clock signal, assert a fourth control signal if a count value reaches a predetermined value K, and be reset in response to the second clock signal, and a logic circuit configured to output the first clock signal as the trigger signal during a period in which the fourth control signal is asserted.

In one embodiment, the logic circuit may be an AND gate configured to output a logical product of the fourth control signal and the first clock signal.

In one embodiment, the controller may further include a fifth counter configured to count the second clock signal and output the reset signal if a count value reaches a predetermined value.

In one embodiment, the semiconductor integrated circuit may further include a timer circuit configured to count the second clock signal to measure a predetermined time.

In one embodiment, the at least one second oscillator may be configured to be calibrated every measurement period of the timer circuit.

In one embodiment, the timer circuit may be configured to generate an enable signal asserted during a first period which is M period of the second clock signal and negated during a second period which is N period of the second clock signal.

In one embodiment, the semiconductor integrated circuit may further include a logic circuit. The first clock signal may be an operation clock of the logic circuit.

In one embodiment, the at least one second oscillator may include a plurality of second oscillators. The plurality of second oscillators may be configured to be calibrated by using the first clock signal generated by the first oscillator which is common to the plurality of second oscillators.

### Embodiment

Hereinafter, preferred embodiments will be described with reference to the drawings. Identical or equivalent components, members and processes shown in each drawing are designated by like reference numerals, and redundant descriptions thereof will be omitted as appropriate. Further, the embodiments are exemplary and do not limit the present disclosure. All features and combinations thereof described in the embodiments are not necessarily essential to the present disclosure.

In the present disclosure, “a state where a member A is connected to a member B” includes a case where the member A and the member B are indirectly connected via any other member that does not affect an electrical connection state between the members A and B or does not impair functions and effects achieved by a combination of the members A and B, in addition to a case where the member A and the member B are physically directly connected.

Similarly, “a state where a member C is installed between a member A and a member B” includes a case where the member A and the member C or the member B and the member C are indirectly connected via any other member that does not affect an electrical connection state between the members A and C or the members B and C or does not impair function and effects achieved by a combination of the members A and C or the members B and C, in addition to a case where the member A and the member C or the member B and the member C are directly connected.

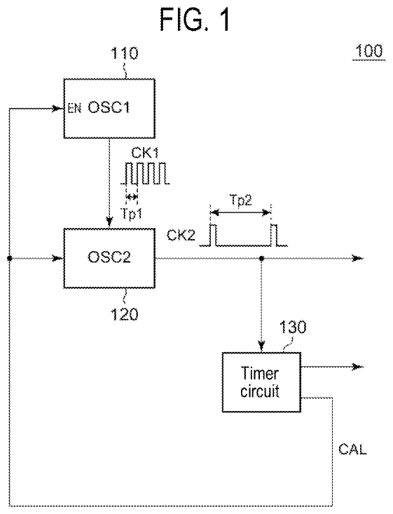

FIG. 1 is a circuit diagram of a semiconductor integrated circuit 100 according to an embodiment. The semiconductor integrated circuit 100 includes a first oscillator 110, a second oscillator 120, and a timer circuit 130.

The first oscillator 110 is configured to generate a first clock signal CK1 having a first frequency f1.

The second oscillator 120 is configured to generate a second clock signal CK2 having a second frequency f2 lower than the first frequency f1. The second oscillator 120 is operated at all times, and the second clock signal CK2 is always available to other circuit blocks of the semiconductor integrated circuit 100.

The timer circuit 130 measures a preset time by counting the second clock signal CK2. The timer circuit 130 may be capable of measuring a plurality of times.

The first oscillator 110 has relatively higher frequency accuracy than the second oscillator 120. In contrast, a circuit area of the first oscillator 110 is larger than that of the second oscillator 120, and power consumption of the first oscillator 110 is larger than that of the second oscillator 120. Both the first oscillator 110 and the second oscillator 120 are relaxation oscillators that charge a capacitor with a constant current and then discharge the capacitor. At least a constant current source and the capacitor of the first oscillator 110 include a configuration having smaller variations than the constant current source and the capacitor of the second oscillator 120.

The second oscillator 120 may be calibrated using the first clock signal CK1. Specifically, the second oscillator 120 may be calibrated so that the second frequency f2 is 1/K times the first frequency f1 (where K is an integer of 8 or more), in other words, so that a period Tp2 of the second clock signal CK2 is K times a period Tp of the first clock signal CK1.

The first oscillator 110 is capable of being switched between an operating state and a stopped state and capable of being stopped during a non-calibration period.

For example, a calibration signal CAL which is asserted (e.g., high) during a calibration period is inputted to the second oscillator 120. The second oscillator 120 is calibrated while the calibration signal CAL is asserted, and oscillates at the second frequency f2 adjusted in a previous calibration period while the calibration signal CAL is negated.

The calibration signal CAL is also supplied to the first oscillator 110. The first oscillator 110 oscillates only during the calibration period in which the calibration signal CAL is asserted and stops during the non-calibration period in which the calibration signal CAL is negated (low).

The calibration signal CAL may be generated by the timer circuit 130. For example, the timer circuit 130 counts the second clock signal CK2 and repeats an operation of keeping the calibration signal CAL high while counting a first predetermined number A, and then keeping the calibration signal CAL low while counting a second predetermined number B.

The foregoing is the basic configuration of the semiconductor integrated circuit 100.

According to the semiconductor integrated circuit 100, the frequency accuracy of the second frequency f2 can be enhanced by calibrating the second oscillator 120 using the first clock signal CK1 having high frequency accuracy during the operation of the semiconductor integrated circuit 100 without trimming the second oscillator 120 during a manufacturing process.

Further, although the first oscillator 110 consumes a large amount of power during operation, the proportion of the power consumption of the first oscillator 110 in the entire semiconductor integrated circuit 100 can be reduced by operating the first oscillator 110 only during the calibration period.

The present disclosure encompasses various devices and methods understood in the block diagram and the circuit diagram of FIG. 1 or derived from the above description and is not limited to a specific configuration. More specific configurations and examples will be described below in order not to narrow the scope of the present disclosure, but to facilitate understanding and clarify the essence and operations of the present disclosure.

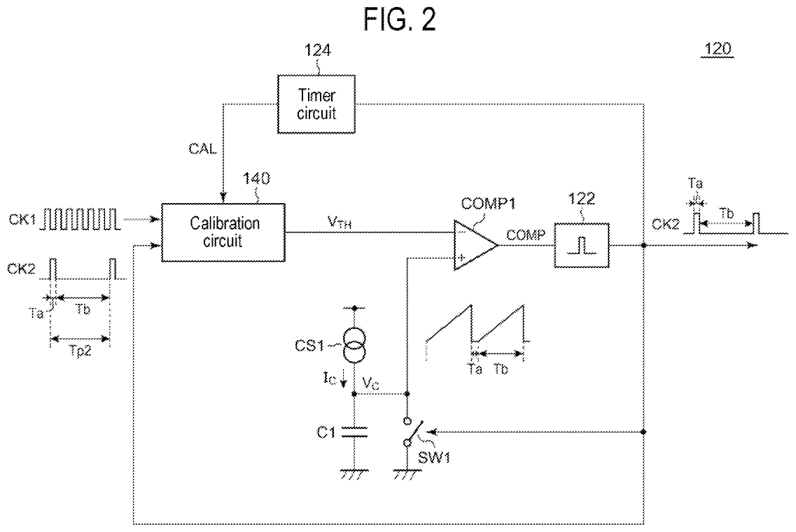

FIG. 2 is a circuit diagram of the second oscillator 120. The second oscillator 120 includes a capacitor C1, a current source CS1, a comparator COMP1, a calibration circuit 140, a discharge switch SW1, and a delay circuit 122.

One end of the capacitor C1 is grounded. The current source CS1 is configured to be connected to the other end of the capacitor C1 and supply a constant current Ic to the capacitor C1. The discharge switch SW1 is configured to be connected in parallel to the capacitor C1. During a period in which the discharge switch SW1 is turned off, a voltage (capacitor voltage) Vc1 generated in the capacitor C1 rises at a constant slope according to equation (1).

Vc1=Ic×t/C1 (1)

The comparator COMP1 is configured to compare a capacitor voltage Vc1 with a threshold voltage V_{TH} and generate a binary comparison signal COMP indicating the comparison result. For example, the comparison signal COMP becomes high if Vc1>V_{TH} and becomes low if Vc1<V_{TH}.

The time required for the capacitor voltage Vc1 to rise from 0 V to the threshold voltage V_{TH} is represented by equation (2).

Tb=C1×V_{TH}/Ic (2)

The delay circuit 122 is configured to receive the comparison signal COMP and generate a pulse signal that becomes high for a predetermined time Ta from a positive edge of the comparison signal COMP. The pulse signal is outputted as a second clock signal CK2. The delay circuit 122 may be a one-shot multivibrator circuit.

During a period in which the second clock signal CK2 is high, the discharge switch SW1 is turned on, electric charges of the capacitor C1 are discharged, and the capacitor voltage Vc1 is reset to 0 V. If the second clock signal CK2 returns to low, the discharge switch SW1 is turned off and the capacitor C1 is charged again.

The second clock signal CK2 is a periodic signal whose high period is Ta and whose low period is Tb. The period Tp2 of the second clock signal CK2 is Ta+Tb.

The calibration circuit 140 is configured to become active during the calibration period and adjust the threshold voltage V_{TH} based on a relationship between the periods (frequencies) of the first clock signal CK1 and the second clock signal CK2.

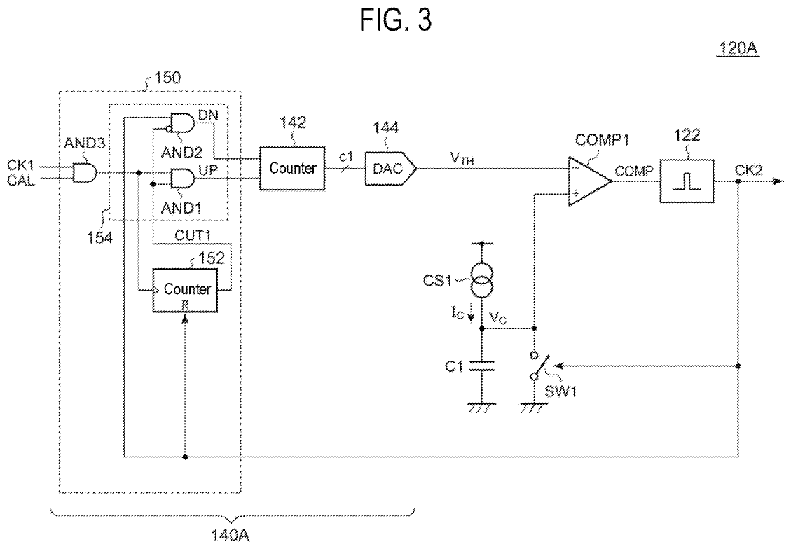

FIG. 3 is a circuit diagram of a second oscillator 120A according to Example 1.

A calibration circuit 140A includes a first counter 142, a D/A converter 144, and a controller 150.

The first counter 142 is configured to count up in response to an up signal UP and count down in response to a down signal DN. The D/A converter 144 converts a count value cl of the first counter 142 to a threshold voltage Vim.

The controller 150 is configured to output the first clock signal CK1 as the up signal UP during a time difference between a period of the first clock signal and a period of the second clock signal if the period of the second clock signal is longer than a time of a predetermined number K times the period of the first clock signal, and is configured to output the second clock signal CK2 as the down signal DN if the period of the second clock signal is shorter than a time of a predetermined number K times the period of the first clock signal.

The controller 150 includes a second counter 152, a logic circuit 154, and a third AND gate AND3. The third AND gate AND3 generates a logical product of the calibration signal CAL and the first clock signal CK1, and allows the first clock signal CK1 to pass only during a period in which the calibration signal CAL is high (gating).

The second counter 152 is configured to count the first clock signal CK1 and assert (e.g., high) a first control signal cnt1 if a count value reaches a predetermined number K. The second counter 152 is reset by the second clock signal CK2.

The logic circuit 154 is configured to output the first clock signal CK1 as the up signal UP while the first control signal cnt1 is asserted and output the second clock signal CK2 as the down signal DN while the first control signal cnt1 is negated.

The logic circuit 154 includes a first AND gate AND1 and a second AND gate AND2. The first AND gate AND1 is configured to output a logical product of the first clock signal CK1 passed through the third AND gate AND3 and the first control signal cnt1 as the up signal UP. The second AND gate AND2 is configured to output a logical product of the second clock signal CK2 and an inverted signal of the first control signal cnt1 as the down signal DN.

The foregoing is a configuration of the second oscillator 120A. Next, an operation thereof will be described.

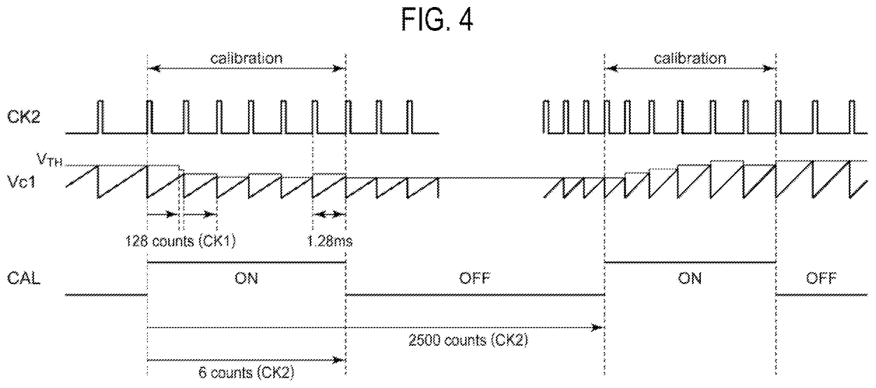

FIG. 4 is a diagram illustrating the operation of the second oscillator 120A of FIG. 3. In this example, A=6 and B=2494. The six periods of the second clock signal CK2 constitute a calibration period, and the calibration signal CAL is asserted.

During the calibration period, an adjustment of the threshold voltage V_{TH} is performed by the controller 150. In this example, K=128, and in a first cycle of the second clock signal CK2, the period of the second clock signal CK2 is assumed to be longer than 128 periods of the first clock signal CK1. In this case, every positive edge of the first clock signal CK1 is outputted as the down signal DN until a positive edge of the second clock signal CK2 is outputted, and the threshold voltage V_{TH} decreases and becomes closer to an optimum value. This operation continues until the period of the second clock signal CK2 becomes shorter than 128 periods of the first clock signal CK1. On the other hand, the period of the second clock signal CK2 is assumed to be shorter than 128 periods of the first clock signal CK1. In this case, the positive edge of the second clock signal CK2 is outputted as the up signal UP, and the threshold voltage V_{TH} increases by one count and becomes closer to the optimum value. This operation continues until the period of the second clock signal CK2 becomes longer than 128 periods of the first clock signal CK1.

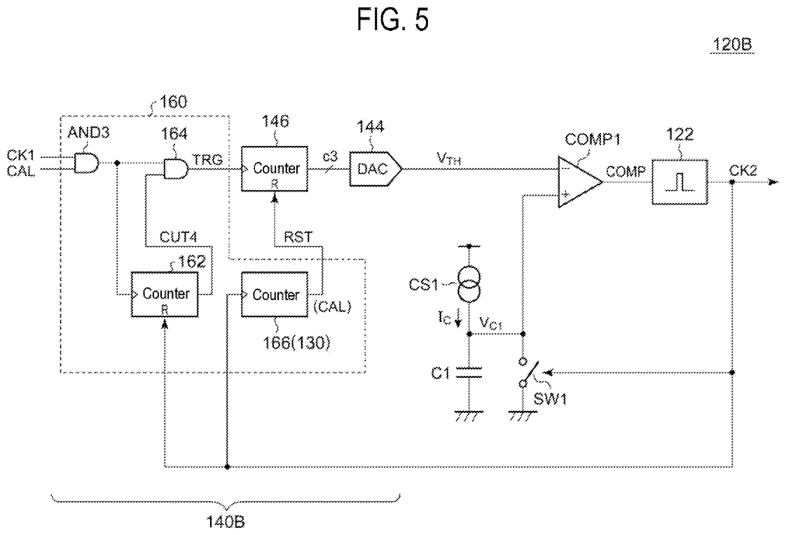

FIG. 5 is a circuit diagram of a second oscillator 120B according to Example 2.

A calibration circuit 140B includes a third counter 146, a D/A converter 144, and a controller 160.

The third counter 146 is configured to perform a counting operation (either a counting-up operation or a counting-down operation) in response to a trigger signal TRG, and a count value c3 is reset in response to a reset signal RST.

The D/A converter 144 is configured to convert the count value c3 of the third counter 146 to a threshold voltage V_{TH}.

The controller 160 is configured to output the first clock signal CK1 as the trigger signal TRG until a next edge (positive edge) of the second clock signal CK2 is generated after K periods of the first clock signal CK1 have elapsed from an edge (e.g., positive edge) of the second clock signal CK2.

The controller 160 includes a fourth counter 162, a logic circuit 164, and a third AND gate AND3.

The fourth counter 162 is configured to count the first clock signal CK1 and assert a fourth control signal cnt4 if a count value c4 reaches a predetermined value K. The fourth counter 162 is configured to be reset in response to the second clock signal CK2.

The logic circuit 164 is configured to output the first clock signal CK1 as the trigger signal TRG during a period in which the fourth control signal cnt4 is asserted. For example, the logic circuit 164 includes an AND gate configured to generate a logical product of the first clock signal CK1 passed through the third AND gate AND3 and the fourth control signal cnt4.

The controller 150 further includes a fifth counter 166. The fifth counter 166 is configured to count the second clock signal CK2 and output a reset signal RST if the count value reaches a predetermined value. The reset signal RST may be the same signal as the calibration signal CAL, and the fifth counter 166 may be a part of the timer circuit 130.

The foregoing is a configuration of the second oscillator 120B. Next, the operation thereof will be described.

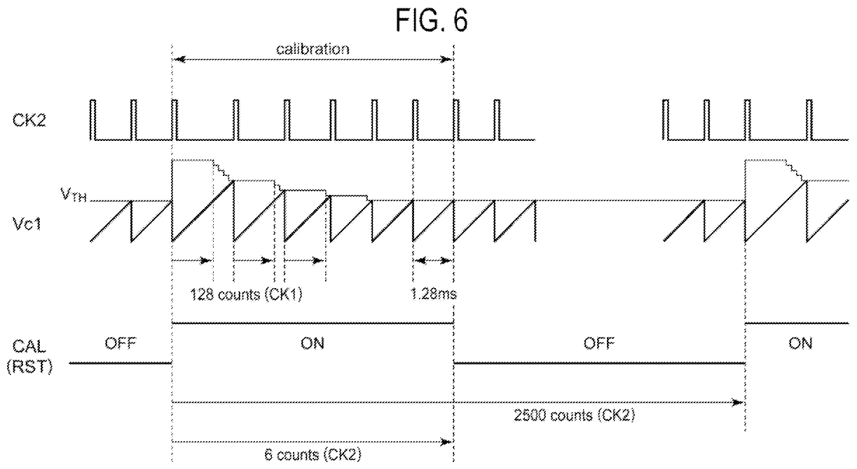

FIG. 6 is a diagram illustrating an operation of the second oscillator 120B of FIG. 5. Similar to FIGS. 4, A=6 and B=2494. The six periods of the second clock signal CK2 constitute a calibration period, and the calibration signal CAL is asserted.

During the calibration period, an adjustment of the threshold voltage V_{TH} is performed by the controller 160. In this example, the third counter 146 performs a counting-down operation. If the reset signal RST is asserted, the count value c3 of the third counter 146 is reset. In this example, K=128, and in a first cycle of the second clock signal CK2, the period of the second clock signal CK2 is assumed to be longer than 128 periods of the first clock signal CK1. In this case, the control signal cnt4 is asserted and supplied to the third counter 146 as the trigger signal TRG, at every positive edge of the first clock signal CK1 until the positive edge of the second clock signal CK2 is outputted. As a result, the count value c3 of the third counter 146 decreases, and the threshold voltage V_{TH} decreases.

In a second cycle of the second clock signal CK2, the period of the second clock signal CK2 is also assumed to be longer than 128 periods of the first clock signal CK1. In this case, the control signal cnt4 is asserted and supplied to the third counter 146 as the trigger signal TRG, at every positive edge of the first clock signal CK1 until the positive edge of the second clock signal CK2 is outputted. As a result, the count value c3 of the third counter 146 decreases, and the threshold voltage V_{TH} decreases.

If the same operation is repeated thereafter, the period of the second clock signal CK2 finally converges to K times (128 times) the period of the first clock signal CK1.

The foregoing is an operation of the second oscillator 120B.

Next, an example of a use of the semiconductor integrated circuit 100 will be described.

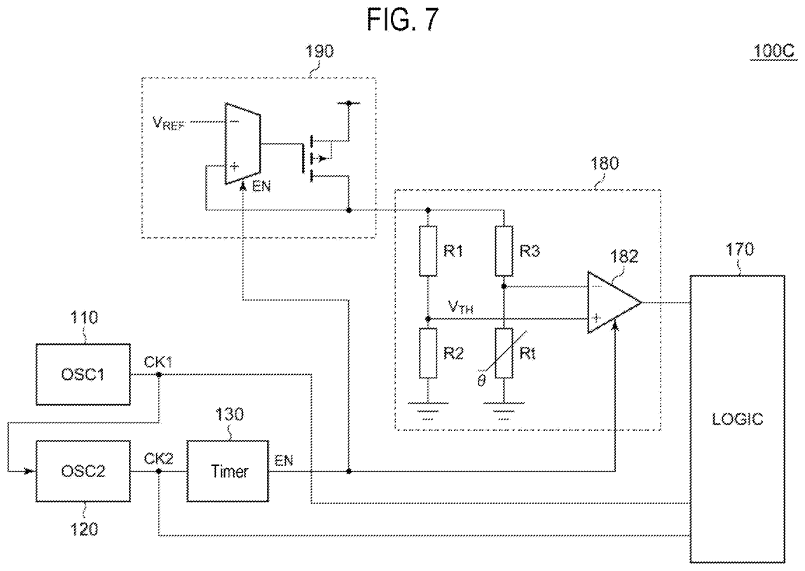

FIG. 7 is a block diagram of a semiconductor integrated circuit 100C. The semiconductor integrated circuit 100C includes a logic circuit 170 and its peripheral circuit in addition to the semiconductor integrated circuit 100 of FIG. 1.

The logic circuit 170 is configured to operate intermittently in response to an enable signal EN generated by the timer circuit 130. The timer circuit 130 is configured to assert (high) the enable signal EN during a first period which is M period of the second clock signal CK2, and negate (low) the enable signal EN during a second period which is N period of the second clock signal CK2.

The enable signal EN may also serve as a calibration signal CAL of the first oscillator 110 and the second oscillator 120.

The logic circuit 170 is configured to operate by using the first clock signal CK1 as an operation clock. For example, in this example, a temperature monitoring circuit 180 and its power supply circuit 190 are installed as peripheral circuits of the logic circuit 170.

The temperature monitoring circuit 180 is configured to compare a temperature of the semiconductor integrated circuit 100C with a threshold value. For example, the temperature monitoring circuit 180 includes resistors R1 to R3, a thermistor Rt, and a comparator 182.

The power supply circuit 190 is configured to be turned on in response to the enable signal EN. For example, the power supply circuit 190 is a voltage follower circuit including a transistor 192 and an error amplifier 194.

The error amplifier 194 can be turned on or off in response to the enable signal EN.

The foregoing is a configuration of the semiconductor integrated circuit 100C.

The enable signal EN is intermittently asserted by the timer circuit 130. Therefore, the power supply circuit 190 is turned on intermittently, and the temperature monitoring circuit 180 operates intermittently. The logic circuit 170 is configured to introduce an output of the temperature monitoring circuit 180 during a period in which the enable signal EN is asserted.

In this configuration, if the first oscillator 110 is stopped, the logic circuit 170 does not operate. Therefore, the first oscillator 110 may be in an operating state only during the calibration period or during the operation period of the logic circuit 170.

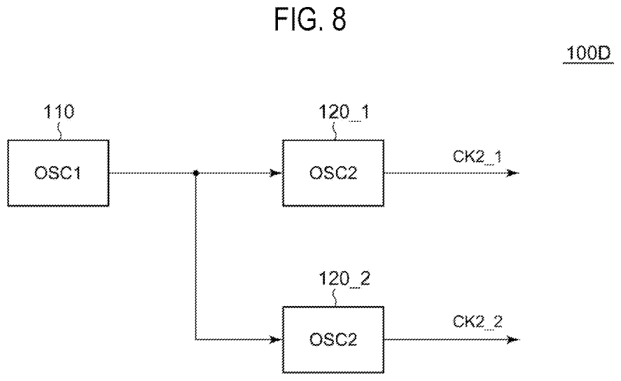

FIG. 8 is a circuit diagram of a semiconductor integrated circuit 100D. The semiconductor integrated circuit 100D includes one first oscillator 110 and a plurality of second oscillators 120_1 to 120_n (here n=2). Each of the second oscillators 120 can be calibrated according to a common first clock signal CK1.

As shown in FIG. 8, in a circuit system including the plurality of second oscillators 120, the technical advantages of the technique according to the present disclosure are more pronounced than in the case where there is only one second oscillator 120.

Although the embodiments according to the present disclosure have been described using specific terms, this description is nothing more than an example for aiding understanding, and is not intended to limit the scope of the present disclosure or the claims. The scope of the present disclosure is defined by the claims. Therefore, embodiments, examples, and modifications not described herein are also included in the scope of the present disclosure.

### SUPPLEMENTARY NOTE

The following technique is disclosed in the subject specification.

(Item 1)

A semiconductor integrated circuit, comprising:
a first oscillator configured to generate a first clock signal having a first frequency; and
at least one second oscillator configured to generate a second clock signal having a second frequency lower than the first frequency,
wherein the first oscillator has relatively higher frequency accuracy than the at least one second oscillator, and
wherein the at least one second oscillator is capable of being calibrated by using the first clock signal, and the first oscillator is capable of being stopped during a non-calibration period.

(Item 2)

The semiconductor integrated circuit of Item 1, wherein the at least one second oscillator is capable of being calibrated such that the second frequency is 1/K times the first frequency, where K is an integer equal to or greater than 8.

(Item 3)

The semiconductor integrated circuit of Item 1 or 2, wherein the at least one second oscillator includes:
a capacitor;
a current source configured to charge the capacitor;
a comparator configured to compare a ramp signal generated in the capacitor with a threshold voltage; and
a calibration circuit configured to adjust the threshold voltage.

(Item 4)

The semiconductor integrated circuit of Item 3, wherein the calibration circuit includes:
a first counter configured to count up in response to an up signal and count down in response to a down signal;
a D/A converter configured to convert a count value of the first counter to the threshold voltage; and
a controller configured to:
   output the first clock signal as the up signal during a time difference between a period of the first clock signal and a period of the second clock signal if the period of the second clock signal is longer than a time of a predetermined number K times the period of the first clock signal; and
   output the second clock signal as the down signal if the period of the second clock signal is shorter than a time of a predetermined number K times the period of the first clock signal.

(Item 5)

The semiconductor integrated circuit of Item 4, wherein the controller includes:
a second counter configured to count the first clock signal, assert the first control signal if a count value reaches the predetermined number K, and be reset by the second clock signal, and
a logic circuit configured to output the first clock signal as the up signal while the first control signal is asserted and output the second clock signal as the down signal while the first control signal is negated.

(Item 6)

The semiconductor integrated circuit of Item 5, wherein the logic circuit includes a first AND gate configured to output a logical product of the first clock signal and the first control signal as the up signal.

(Item 7)

The semiconductor integrated circuit of Item 5 or 6, wherein the logic circuit includes a second AND gate configured to output a logical product of the second clock signal and an inverted signal of the first control signal as the down signal.

(Item 8)

The semiconductor integrated circuit of Item 3, wherein the calibration circuit includes:
a third counter configured to perform a counting operation in response to a trigger signal and have a count value reset in response to a reset signal;
a D/A converter configured to convert the count value of the third counter to the threshold voltage; and
a controller configured to output the first clock signal as the trigger signal until a next edge of the second clock signal is generated after K periods of the first clock signal have elapsed from an edge of the second clock signal.

(Item 9)

The semiconductor integrated circuit of Item 8, wherein the controller includes:
a fourth counter configured to count the first clock signal, assert a fourth control signal if a count value reaches a predetermined value K, and be reset in response to the second clock signal, and
a logic circuit configured to output the first clock signal as the trigger signal during a period in which the fourth control signal is asserted.

(Item 10)

The semiconductor integrated circuit of Item 9, wherein the logic circuit is an AND gate configured to output a logical product of the fourth control signal and the first clock signal.

(Item 11)

The semiconductor integrated circuit of Item 7, wherein the controller further includes a fifth counter configured to count the second clock signal to output the reset signal when a count value reaches a predetermined value.

(Item 12)

The semiconductor integrated circuit of any one of Items 1 to 8, further comprising:
a timer circuit configured to count the second clock signal to measure a predetermined time.

(Item 13)

The semiconductor integrated circuit of Item 9, wherein the at least one second oscillator is configured to be calibrated every measurement period of the timer circuit.

(Item 14)

The semiconductor integrated circuit of Item 9 or 10, wherein the timer circuit is configured to generate an enable signal asserted during a first period which is M period of the second clock signal and negated during a second period which is N period of the second clock signal.

(Item 15)

The semiconductor integrated circuit of Item 11, further comprising:
a logic circuit,
wherein the first clock signal is an operation clock of the logic circuit.

(Item 16)

The semiconductor integrated circuit of any one of Items 1 to 12, wherein the at least one second oscillator includes a plurality of second oscillators, and
wherein the plurality of second oscillators is calibrated using the first clock signal generated by the first oscillator which is common to the plurality of second oscillators.

According to the present disclosure in some embodiments, it is possible to suppress variations in the oscillation frequency of an oscillator.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor integrated circuit, comprising:
a first oscillator configured to generate a first clock signal having a first frequency; and
at least one second oscillator configured to generate a second clock signal having a second frequency lower than the first frequency,
wherein the first oscillator has relatively higher frequency accuracy than the at least one second oscillator, and
wherein the at least one second oscillator is capable of being calibrated by using the first clock signal, and the first oscillator is capable of being stopped during a non-calibration period.

2. The semiconductor integrated circuit of claim 1, wherein the at least one second oscillator is capable of being calibrated such that the second frequency is 1/K times the first frequency, where K is an integer equal to or greater than 8.

3. The semiconductor integrated circuit of claim 1, wherein the at least one second oscillator includes:
a capacitor;
a current source configured to charge the capacitor;
a comparator configured to compare a ramp signal generated in the capacitor with a threshold voltage; and
a calibration circuit configured to adjust the threshold voltage.

4. The semiconductor integrated circuit of claim 3, wherein the calibration circuit includes:
a first counter configured to count up in response to an up signal and count down in response to a down signal;
a D/A converter configured to convert a count value of the first counter to the threshold voltage; and
a controller configured to:
output the first clock signal as the up signal during a time difference between a period of the first clock signal and a period of the second clock signal if the period of the second clock signal is longer than a time of a predetermined number K times the period of the first clock signal; and
output the second clock signal as the down signal if the period of the second clock signal is shorter than a time of a predetermined number K times the period of the first clock signal.

5. The semiconductor integrated circuit of claim 4, wherein the controller includes:
a second counter configured to count the first clock signal, assert a first control signal if a count value reaches the predetermined number K, and be reset by the second clock signal; and
a logic circuit configured to output the first clock signal as the up signal while the first control signal is asserted and output the second clock signal as the down signal while the first control signal is negated.

6. The semiconductor integrated circuit of claim 5, wherein the logic circuit includes a first AND gate configured to output a logical product of the first clock signal and the first control signal as the up signal.

7. The semiconductor integrated circuit of claim 5, wherein the logic circuit includes a second AND gate configured to output a logical product of the second clock signal and an inverted signal of the first control signal as the down signal.

8. The semiconductor integrated circuit of claim 3, wherein the calibration circuit includes:
a third counter configured to perform a counting operation in response to a trigger signal and have a count value reset in response to a reset signal;
a D/A converter configured to convert the count value of the third counter to the threshold voltage; and
a controller configured to output the first clock signal as the trigger signal until a next edge of the second clock signal is generated after K periods of the first clock signal have elapsed from an edge of the second clock signal.

9. The semiconductor integrated circuit of claim 8, wherein the controller includes:
a fourth counter configured to count the first clock signal, assert a fourth control signal if a count value reaches a predetermined value K, and be reset in response to the second clock signal; and
a logic circuit configured to output the first clock signal as the trigger signal during a period in which the fourth control signal is asserted.

10. The semiconductor integrated circuit of claim 9, wherein the logic circuit is an AND gate configured to output a logical product of the fourth control signal and the first clock signal.

11. The semiconductor integrated circuit of claim 9, wherein the controller further includes a fifth counter configured to count the second clock signal and output the reset signal if a count value reaches a predetermined value.

12. The semiconductor integrated circuit of claim 1, further comprising:
a timer circuit configured to count the second clock signal to measure a predetermined time.

13. The semiconductor integrated circuit of claim 12, wherein the at least one second oscillator is configured to be calibrated every measurement period of the timer circuit.

14. The semiconductor integrated circuit of claim 12, wherein the timer circuit is configured to generate an enable signal asserted during a first period which is M period of the second clock signal and negated during a second period which is N period of the second clock signal.

15. The semiconductor integrated circuit of claim 1, further comprising a logic circuit,
wherein the first clock signal is an operation clock of the logic circuit.

16. The semiconductor integrated circuit of claim 1, wherein the at least one second oscillator includes a plurality of second oscillators, and
wherein the plurality of second oscillators is configured to be calibrated by using the first clock signal generated by the first oscillator which is common to the plurality of second oscillators.
